(19) United States
(12) Patent Application Publication
(10) Pub. No.: US 2016/0343455 A1
(43) Pub. Date: Nov. 24, 2016

(54) REMAPPING MEMORY LOCATIONS IN A MEMORY ARRAY

(71) Applicant: HEWLETT PACKARD ENTERPRISE DEVELOPMENT LP, Houston, TX (US)

(72) Inventors: Gregg B. LESARTRE, Fort Collins, CO (US); Naveen MURALIMANOHAR, Santa Clara, CA (US)

(21) Appl. No.: 15/114,950

(22) PCT Filed: Jan. 31, 2014
(86) PCT No.: PCT/US2014/014018

§ 371 Date: Jul. 28, 2016

(51) Int. Cl. G11C 29/00; G11C 29/12; G06F 11/10; G06F 12/02

(52) U.S. Cl. CPC G11C 29/76; G06F 12/0223; G11C 29/82; G11C 29/12; G06F 11/1004; G06F 2212/1032

(57) ABSTRACT

A method for remapping a memory location in a memory array is described. The method includes receiving, by a memory manager, an identification of a first memory location in a memory array that is to be remapped using a remapping procedure performed by a memory manager. The remapping procedure includes selecting a second memory location to store data intended for the first memory location. The procedure also includes writing, in the first memory location, a pointer to the second memory location.

### BACKGROUND

Memory die manufacturers benefit from having high yield rates. Yield rates indicate the percentage of blocks that are manufactured that can be used by customers. Memory dies may not use bad memory blocks, so as to ensure the memory die maintains data integrity. To achieve higher yield rates, memory die manufacturers test memory dies to discover bad memory blocks. When a bad memory block is identified, the bad block may be replaced with an additional memory block manufactured into the memory die.

### BRIEF DESCRIPTION OF THE DRAWINGS

The accompanying drawings illustrate various examples of the principles described herein and are a part of the specification. The examples do not limit the scope of the claims.

FIG. 1 is a diagram of a system for remapping memory locations in a memory array according to one example of the principles described herein.

FIG. 2 is a flowchart of a method for remapping memory locations in a memory array according to one example of the principles described herein.

FIG. 3 is a flowchart of another method for remapping memory locations in a memory array according to one example of the principles described herein.

FIG. 4 is a diagram of a number of memory dies that include remapped memory locations and remapped memory blocks according to one example of the principles described herein.

FIG. 5 is a diagram of a memory manager for remapping memory locations in in a memory array according to one example of the principles described herein.

FIG. 6 is a diagram of a memory manager for remapping memory locations in a memory array according to one example of the principles herein.

Throughout the drawings, identical reference numbers designate similar, but not necessarily identical, elements.

### DETAILED DESCRIPTION

Memory blocks are used to store data. A number of memory blocks may be positioned on a memory die. During manufacturing a number of memory blocks within a memory die may be “bad” due to the manufacturing process. Memory dies may not use bad memory blocks, so as to ensure the memory die maintains data integrity. Accordingly, memory die manufacturers may include a number of spare memory resources such that a memory die may have sufficient memory blocks to operate as advertised.

To this end, manufacturing companies may test memory dies to discovery memory blocks that contain manufacturing defects. A memory die that fails a manufacturing test may not be used, since the failure in the memory die may result in inconsistent data storage. To account for the “bad” memory blocks, manufacturers may design dies to have additional memory resources available, in order to replace memory blocks within a memory die that have failed. When the manufacturer detects a failure error in a memory block, the additional resources may be used to replace the bad memory block. While such testing may reduce the negative impact of “bad” memory allocations, these tests may include some inefficiencies.

For example, the testing may be performed at a course granularity. Accordingly, the additional resources may be relatively large, and may be used in replacing large memory blocks of the manufactured die. Such coarse granularity may lead to wasted memory space. For example, when a memory block has a relatively small failure, such as a single bit failure, the entire memory block may be replaced. In other words, a number of memory bits that have not failed, and may otherwise be used to store data, may be replaced due to the failure of a single memory bit. Accordingly, even small failures, such as single bit failures, encourage manufacturers to implement extra data capacity to handle the failures.

Still further, replacing large portions of the memory die with additional resources may increase the cost to manufacturers as greater amounts of additional resources may be used. In some cases, manufacturers may also have higher rates of dies that may not pass testing, because there are not enough additional resources to account for the number of errors experienced on a memory die.

In light of these and other complications, the systems and methods presented in this disclosure allow for a more efficient remapping of memory locations in a memory array. More specifically, the systems and methods disclosed herein allow a memory tester to remap larger memory blocks while allowing a memory manager, using a remapping procedure, to remap smaller memory locations. In other words. the memory manager may use a finer grain remapping when needed. One example of a fine-grain remapping is a fine grained remapping with error checking and correcting and embedded pointers (FREE-p) mapping function which creates a pointer associated with a memory location when inconsistent data is discovered.

Such a method may be beneficial by allowing small failures to be corrected using methods that are more efficient than replacing a large memory block. In some examples, the memory tester may communicate to the memory manager which memory locations have failed, allowing the memory manager to correct the failures using less of the additional resources manufactured in the memory die. Moreover, using a fine-grained remapping procedure such as FREE-p may be beneficial in that it allows for manufacturing remapping to be performed without additional resources. For example, during use, a fine grain remapping such as FREE-p may be used to detect and remap memory location during use. This same FREE-p mechanism may be used in a manufacturing scenario to remap memory locations that are defective due to the manufacturing process. In other words, the FREE-p remapping mechanism may be beneficial in that it may be used during operation as well as during manufacturing to identify defective memory locations.

Managing the communication between the memory tester and the memory manager may allow the memory tester to avoid using additional resources in the memory die to handle small failures, such as single bit failures. Instead, the memory manager may address these failures.

The memory manager may receive an indication of a memory location that is to be remapped, and may remap the memory location. The remap may create a pointer associated with the memory location when a data inconsistency is discovered. The memory manager may remap data intended for the identified memory location to memory locations that have not failed. A memory manager may remap the identified memory locations by using unused memory locations, leaving the additional resources on the memory die available for repair of failures that would not be resolved by the memory manager.

In some examples, the memory manager may receive data regarding memory locations in a memory array to be remapped by examining the memory array for patterns written in a memory testing process. The patterns may indicate the memory locations within a memory array that are to be remapped. The receipt of data regarding memory locations may involve reading a data file, reading a pattern from the memory or combinations thereof.

The memory manager may receive the identification of a first memory location in a memory array that is to be remapped. The reception may occur through any data communication method, such as reading a file on the memory array, examining patterns in the memory array, receiving data through a networking protocol, receiving data through an inter-process communication protocol, or similar method or combination of methods.

The memory manager may then remap the first memory location by selecting a second memory location in the memory array to receive data intended for the first memory location. The memory manager may remap the first memory location by reserving the second memory location in the memory array. A memory manager may reserve a memory location by selecting the memory block from the list of free memory locations in the memory array. The memory manager may also reserve memory locations in the memory array for handling failures, and maintain data to manage the reserved memory location.

The memory manager may initiate the remapping by writing remapping data to the memory array. The remapping data may include a pointer to the new memory block to store data and a status bit to indicate a memory block has been remapped.

The memory manager may receive the identification of the memory location from a memory tester, or the memory manager may receive the identification of the memory location from a module in the memory manager. The identification may be received from a single device, or may be communicated between devices.

The present disclosure describes a method for remapping a memory location in a memory array. The method may include receiving, by a memory manager, an identification of a first memory location in a memory array that is to be remapped using a remapping procedure performed by a memory manager. The remapping procedure may include selecting a second memory location to store data intended for the first memory location. The remapping procedure may also include writing, in the first memory location, a pointer to the second memory location.

The present disclosure describes a system for remapping a memory location in a memory array. The system may include a processor and memory communicatively coupled to the processor. The system may also include a memory manager. The memory manager may include a receiver for receiving information about a first memory location to remap. The memory manager may also include a remapper to remap the first memory location to a second memory location.

The present disclosure describes a computer program product for remapping a memory location in a memory array. The computer program product may include a computer readable storage medium that includes computer usable program code embodied therewith. The computer usable program code may include computer usable program code which, when executed by a processor may receive information regarding a first memory location in a memory array may be remapped. The computer usable program code may include computer usable code to, when executed by a processor, select a second memory location in the memory array to store data intended for the first memory location. The computer usable program code may include computer usable code which, when executed by a processor, remaps the first memory location to the second memory location.

The handling of remapping of memory locations as described herein may allow a memory manager to reduce usage of the additional resources built in a memory die. Reducing dependencies on the additional resources built into a memory die may allow manufacturers to increase yields of good memory arrays. A memory manager may handle memory remapping in a manner that can scale with memory capacity.

As used in the present specification and in the appended claims, a “memory array” or “memory” may refer to memory controlled by a memory manager.

Further, as used in the present specification and in the appended claims, a “memristor memory,” “memristor,” “memristor element,” or similar terminology may refer to a single passive circuit element that may maintain a relationship between the time integrals of current and voltage across a two terminal element. In some examples, memristors may be used as memory elements of the memory array. For example, the memristor elements in a memory array may be organized in a structure to facilitate a dense packing of memristor elements to support construction of a large capacity memory die.

Still further, as used in the present specification and in the appended claims, the term “memory die” may refer to a memory unit that is divided into a number of memory blocks. A memory block may include a number of memory bits.

Even further, as used in the present specification and in the appended claims, the term “memory location” may refer to a divisional unit of a memory array. A “memory location” may include bits from memory blocks residing on different memory dies.

Yet further, as used in the present specification and in the appended claims, the term “a number of” or similar language may include any positive number including one to infinity; zero not being a number, but the absence of a number.

In the following description, for purposes of explanation, numerous specific details are set forth in order to provide a thorough understanding of the present systems and methods. It will be apparent, however, to one skilled in the art, that the present apparatus, systems, and methods may be practiced without these specific details. Reference in the specification to “an example” or similar language means that a particular feature, structure, or characteristic described in connection with that example is included as described, but may not be included in other examples.

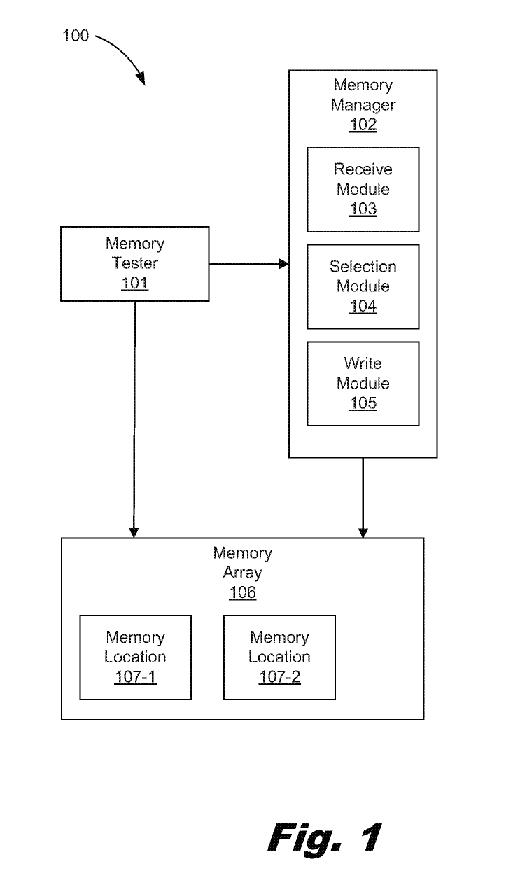

FIG. 1 is a diagram of a system (100) for remapping memory locations (107) in a memory array (106) according to one example of the principles described herein. The system (100) may include a memory tester (101) to test a memory array (106) for failed memory locations (107) and to remap memory blocks within a memory array (106). In some examples. the memory array (106) may include a number of memristor components. The memory array (106) may be a cross bar memory array.

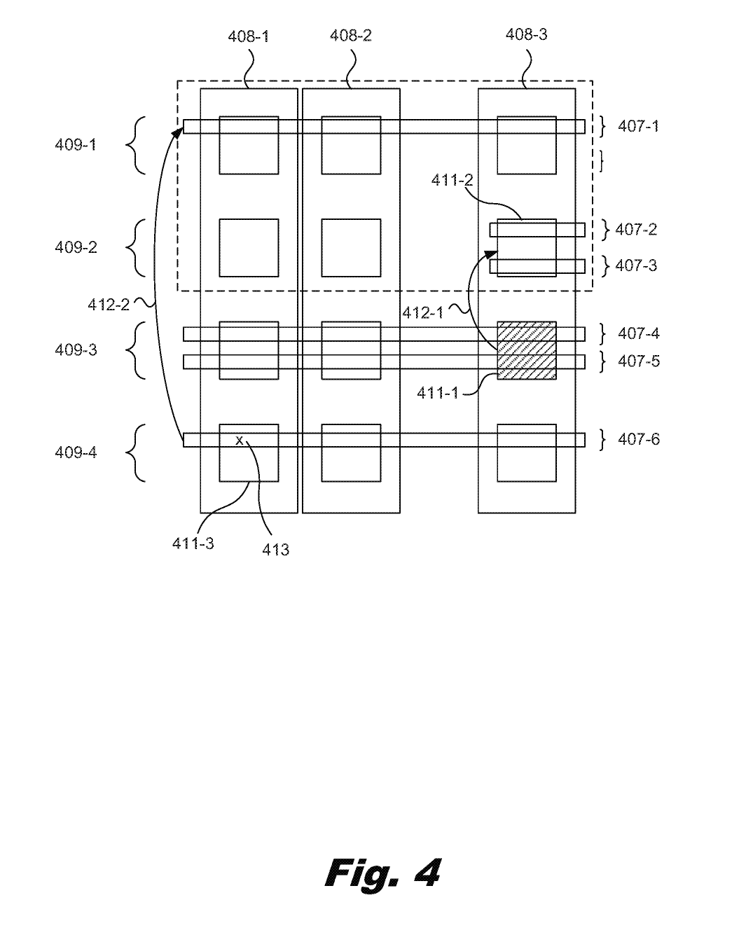

In some examples, the memory tester (101) may send an indication of memory locations (107) to be remapped to the memory manager (102). For example, the memory tester (101) may test a memory die. The memory tester (101) may then indicate to the memory manager (102), memory locations (107) within a memory die that have failed. In some examples, the indication of memory locations (107) to be remapped by the memory manager (102) may relate to smaller failures as compared to those remappings performed by the memory tester (101). More detail concerning the detection of failed memory locations (107) and failed memory blocks is given below in connection with FIG. 4.

A memory tester (101) may test a unit manufactured for memory usage, such as a memory die. The memory die may contain a number of memory arrays (106). A memory tester (101) may use additional resources on a memory die to replace memory blocks and to prevent memory blocks that have failed from being used.

The system (100) may also include a memory manager (102) to receive an identification of a first memory location (107-1) that is to be remapped using a remapping procedure performed by the memory manager (102). For example, an identification of a first memory location (107-1) may be received from a memory tester (101).

The memory manager (102) may include a number of modules to carry out the functionality described herein. For example, the memory manager (102) may include a receive module (103) to receive an identification of a first memory location (107-1) in a memory array (106) that is to be remapped using a remapping procedure. In some examples, the identification of the first memory location (107-1) may be received from the memory tester (101). In other examples, the identification may be received from another component within the memory manager (102). Remapping may then be divided between the memory tester (101) and the memory manager (102). A memory manager (102) may be used to handle remapping relatively small memory failures. This may be done by remapping memory addressing to replace one memory location (107) with another. By comparison, the memory tester (101) may be used to handle the remapping of the larger memory blocks. Receiving an identification of a first memory location (107-1) to be remapped by the memory manager (102) may be beneficial as the memory manager (102) may handle errors in a manner that may be more efficient than other stages of the memory verification process.

After the indication information is received by the receive module (103), a selection module (104) may select a second memory location (107-2) to store data intended for the first memory location (107-1). For example, the selection module (104), upon detection that a first memory location (107-1) is to be remapped, may select a second memory location (107-2) from a free memory location list. The address of the second memory location (107-2) may then be stored in the memory array (106) by a write module (105) for future usage.

The selection module (104) may identify and select, based on the information received, a second memory location (107-2) to store and retrieve data intended for the first memory location (107-1). The selection module (104) may select available memory locations (107) in the memory array (106). Available memory locations (107) may be found on a list of free memory locations (107), may be reserved for purposes such as handling memory errors, or may be obtained through some alternative method.

The selection module (104) may select a second memory location (107-2) that is sized to reduce discarding memory locations (107) that are functioning correctly. As an example, a memory array (106) may have a single memory location (107) with a single bit failure which may be replaced by another memory location (107), as where an alternative error handling routine may map out an entire row or a column of bits or an entire memory block even for a single bit failure. Mapping out an entire row or a column of bits for a single bit failure may waste many working bits.

Through effective selection of a second memory location (107-2), the selection module (104) may reduce the amount of “good” or properly functioning memory locations (107) that are removed from usage due to the good memory locations (107) association with a bad memory block.

A write module (105) may write, in the first memory location (107-1) a pointer to the second memory location (107-2). In some examples, the functionality carried out by the selection module (104) and the write module (105) may be a remapping procedure. In some examples, the remapping procedure may be performed at a cache line granularity.

An example of a remapping procedure is given as follows. A memory array (106) may include a first memory location (107-1) and second memory location (107-2). As described above, in some examples, a memory location (107) may include a number of failed memory bits. For example, the first memory location (107-1) may include a failed memory bit. However, while the first memory location (107-1) may include a failed memory bit, a number of memory bits within the first memory location (107-1) may be available for use. In this example, a number of the available bits within the failed memory location (107-1) may be used to remap the data represented in that first memory location (107-1) to the second memory location (107-2).

For example, a pointer to the second memory location (107-2) may be included in the first memory location (107-1) such that the “bad” memory location remains usable. The remapping procedure may utilize memory locations (107) that include failed bits to store a pointer that indicates where the data has been remapped to. In some examples, the pointer may be much smaller than the memory location (107) that it is remapping. In some examples, a status bit may be used to indicate that a particular memory location (107) includes remapped data. In other words, although the first memory location (107-1) may include a number of failed bits, the remapping procedure may utilize space within the bad first memory location (107-1) to include a pointer that indicates the data remapping. Such a remapping procedure may be a fine-grained remapping with error correcting code and embedded pointers (FREE-p) mapping. The memory manager (102) may perform other functions, and may be associated with the memory array (106), or may be part of a device that utilizes the memory array (106). Placing a remapping pointer in the “bad” first memory location (107-1) may be beneficial in that it may eliminate additional required storage for the remapping pointer.

A memory manager (102) may correct errors on a memory array (106) using methods that may not alter a circuit on a memory die. The memory manager (102) may remap a memory location (107) using a pointer, status bit, or combination thereof to remap data from a first memory location (107-1) with a failure to a second memory location (107-2) that does not have a failure. The memory manager may encode date to ensure that the failure in the memory location does not cause data inconsistency.

The write module (105) may store an association between the identification of a first memory location (107-1) and the second memory location (107-2). The data stored may include a pointer to the second memory location (107-2). The write module (105) may store the association between the first memory location (107-1) and the second memory location (107-2). The association may be stored in the memory array (106), or may be stored on an alternative device for future reference.

Fine grained handling of memory failures by the memory manager (102) may allow a memory tester (101) to use additional memory resources on the memory die to handle large failures that may encompass a memory block. The decreased demand on the additional memory resources may allow for the same memory resources to be used to handle additional failure situations. The memory resources on the memory die may then increase the chip yields, or percentage of the chips that are capable of operating without error. Alternatively, the additional memory resources may be used as additional memory to increase the capacity of the memory array (106).

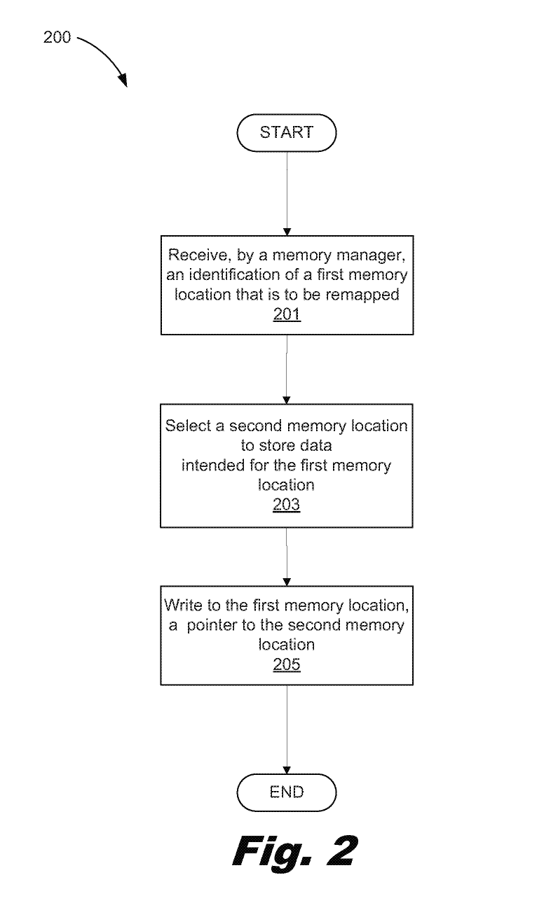

FIG. 2 is a flowchart of a method (200) for remapping memory locations (FIG. 1, 107) according to one example of the principles described herein. The method (200) may allow for receiving identification of a first memory location (FIG. 1, 107-1) and remapping the first memory location (FIG. 1, 107-1) by selecting a second memory location (FIG. 1, 107-2) to store data intended for the first memory location (FIG. 1, 107-1), and writing the selection to the first memory location (FIG. 1, 107-1).

The method (200) may include receiving (block 201) by a memory manager (FIG. 1, 102) an identification of a first memory location (FIG. 1, 107-1) in a memory array (FIG. 1. 106) that is to be remapped. The identification of the first memory location (FIG. 1, 107-1) may be received from a memory tester (FIG. 1, 101), or may be received from an indication module.

For example, a memory tester (FIG. 1, 101) may indicate memory locations (FIG. 1, 107) where bit failures have been found such that the memory manager (FIG. 1, 102) using a remapping procedure such as FREE-p may remap the memory location (FIG. 1, 107). In some examples, the indication may be included in a data file. As will be described below, the memory manager (FIG. 1, 102) may then read the data file to identify the memory location (FIG. 1, 107) to be remapped.

In another example, the indication may be encoded in a pattern. In this example, the memory manager (FIG. 1, 102) may read the pattern indicated to identify a memory location (FIG. 1, 107) that is to be remapped. In some examples, the memory tester (FIG. 1, 101) may test memory at a memory die level. In other words, the received pattern may indicate a memory block on a memory die has failed. However, as will be described below in connection with FIG. 4, the remapping procedure may be performed across multiple memory dies.

In some examples, the first memory location (FIG. 1 107-1) to be remapped may be distinct from a memory block of the memory array (FIG. 1, 106) that is remapped by the memory tester (FIG. 1, 101). For example, the memory tester (FIG. 1, 101) may remap memory blocks and may leave the remapping of single memory locations (FIG. 1, 107) to the fine grained remapping procedure used by the memory manager (FIG. 1, 102).

The method (200) may include selecting (block 203) a second memory location (FIG. 1, 107-2) to store data intended for the first memory location (FIG. 1, 107-1). Selection (block 203) of the second memory location (FIG. 1, 107-2) may include selecting memory locations (FIG. 1, 107) that are not in use. Memory locations (FIG. 1, 107) that are not in use may be associated with a free list, or may be reserved for specific purposes, such as handling errors.

Selection (block 203) of a second memory location (FIG. 1, 107-2) may allow the memory manager (FIG. 1, 102) to select an alternative memory location (FIG. 1, 107) to reduce the amount of properly functioning memory that is removed from use due to an association with a memory block that has failed.

The method (200) may include writing (block 205) to the first memory location (FIG. 1, 107-1) a pointer to the second memory location (FIG. 1, 107-2). The write may be associated with the identification of the first memory location (FIG. 1, 107-1), or may be located in any area of the memory managed by the memory manager (FIG. 1, 102). The pointer may include the identification of the second memory location (FIG. 1, 107-2). The method (200) may also include writing a status bit to indicate a pointer as such, and to indicate that the pointer is not data. The method (200) may write some or all of the information, and the information may or may not be written to a single memory location (FIG. 1, 107) of the memory array (FIG. 1, 106).

Selecting (block 203) a second memory location (FIG. 1, 107-2) and writing (block 205) a pointer to the first memory location (FIG. 1, 107-1) may be referred to as a remapping procedure. In some examples, the remapping procedure may be a fine grained remapping with error checking and correcting and embedded pointers (FREE-p) mapping function. Using a FREE-p mapping function, the memory manager (FIG. 1, 102) may use a status bit to indicate that a memory location (FIG. 1, 107) such as the first memory location (FIG. 1, 107-1) has been remapped. The memory manager (FIG. 1, 102) may also use a remap pointer to indicate the location of the second memory location (FIG. 1, 107-2). As such, the remapping procedure used by the memory manager (FIG. 1, 102) may be performed with less memory utilization than a remapping performed by a memory tester (FIG. 1, 101), and without providing a separate remapping structure for this purpose.

The method (200) as described herein may be beneficial in that small errors are handled by an efficient remapping procedure via the memory manager (FIG. 1, 102) while larger errors may be addressed by the memory tester (FIG. 1, 101).

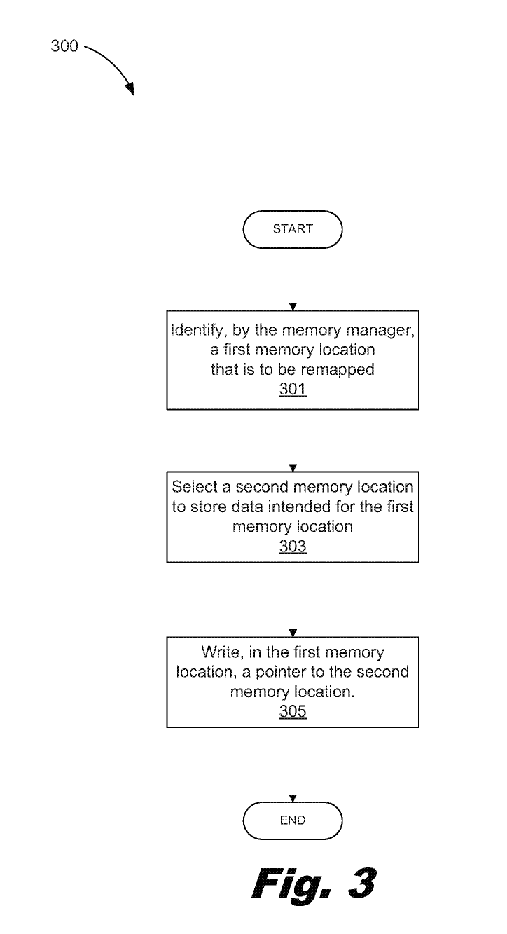

FIG. 3 is a flowchart of another method (300) for remapping memory locations (FIG. 1, 107) in a memory array (FIG. 1, 106) according to one example of the principles described herein. The method (300) may include identifying (block 301), by the memory manager (FIG. 1, 102), the first memory location (FIG. 1, 107-1). In some examples, the memory tester (FIG. 1, 101) may ignore small bit failures, such as single bit failures. In this example, the memory tester (FIG. 1, 101) may remap larger memory blocks. Similarly, in this example, the memory manager (FIG. 1, 102) may include an identification module to identify (block 301) the first memory location (FIG. 1, 107-1). In this example. when an access to a memory location (FIG. 1, 107) is first attempted in an assembled memory die, the write may fail, and the memory manager (FIG. 1, 102) may remap the memory location (FIG. 1, 107) as described below. For example, the memory manager (FIG. 1, 102) may select (block 303) a second memory location to store data intended for the first memory location (FIG. 1, 107-1). This may be performed as described in connection with FIG. 2. The memory manager (FIG. 1, 102) may write (block 305) in the first memory location (FIG. 1, 107-1) a pointer to the second memory location (FIG. 1, 107-2).

FIG. 4 is a diagram of a number of memory dies (408) that in de remapped memory locations (407) and remapped memory blocks (411) according to one example of the principles described herein. As described above, the system (FIG. 1, 100) may include a number of memory dies (408). For example, the system (FIG. 1, 100) may include a first memory die (408-1), a second memory die (408-2), and a third memory die (408-3). While FIG. 4 depicts three memory dies (408), the system (FIG. 1, 100) may include any number of memory dies (408).

Each memory die (408) may include a number of memory blocks (411). For simplicity, a few memory blocks (411-1, 411-2, 411-3) are referenced by a number, however each memory block (411) depicted in FIG. 4 may be similar to the memory blocks (411-1, 411-2, 411-3) indicated by reference numbers. Specific reference to groups of memory blocks (411) may be made with respect to different rows (409). For example, a first row (409-1) may include a memory block (411) from each of the first memory die (408-1), the second memory die (408-2), and the third memory die (408-3).

In some examples, one or more memory blocks (411) may be designated to store data. For example, the third row (409-3) of memory blocks (411) and the fourth row (409-4) of memory blocks (411) may be designated to store data. By comparison, a number of other rows (409) of memory blocks (411) may be designated as additional resources to receive data when memory blocks (411) in the storage rows (409-3, 409-4) fail. For example, the first row (409-2) of memory blocks (411) and the second row (409-2) of memory blocks (411) may be designated as additional resources as indicated by the dashed box in FIG. 4. While specific reference is made to a particular number and a particular orientation of rows (409) as storage rows (409-3, 409-4) and additional resource rows (409-1, 409-2), any number and any orientation of rows (409) may be used as described herein.

The memory may be also divided by memory locations (407). As described above, memory locations (407) may refer to divisions of memory blocks (411) that span a number of memory dies (408). For example, a memory location (407) may divide multiple memory blocks (411) that reside on different memory dies (408). More specifically, a memory location (407-1) may divide a number of memory blocks (411) on the first memory die (408-1), the second memory die (408-2), and the third memory die (408-3). A particular memory block (411) may include a number of memory locations (407). For example, a first memory block (411-1) may include a number of memory locations (407-4, 407-5). For simplicity, one or two memory locations (407) are indicated as dividing the memory blocks (411), however any number of memory locations (407) may be used to divide memory blocks (411) within memory dies (408).

As described above, in some examples, a memory tester (FIG. 1, 101) may remap memory blocks (411). For example, a memory block (411) may fail for any number of reasons including defects resulting from the manufacturing process or a short in a wiring component. As depicted in FIG. 4, the first memory block (411-1) may fail as indicated by the diagonal lines. In this example, a memory tester (FIG. 1, 101) may remap the failed first memory block (411-1) to another memory block (411). More specifically, the memory tester (FIG. 1, 101) may remap the first memory block (411-1) to the second memory block (411-2). The second memory block (411-2) may be included in a row (409-2) of memory blocks (411) that is designated as additional resources to be used in the event of a failed memory block (411). The remapping of the memory block (411) may be indicated by the arrow (412-1). In this example, the portions of the memory locations (407-4, 407-5) that correspond to the failed memory block (411-1) may be remapped to memory locations (407-2, 407-3) of the second memory block (411-2). However, the portions of the memory locations (407-4, 407-5) that correspond to memory blocks (411) in the same row (409-3) as the failed memory block (411-1) but that have not failed, are maintained in the original row (409-3). While remapping an entire memory block (411) may be beneficial, it may also waste memory space. For example. as described above. if a single bit within a memory block (411-1) fails, an entire failed memory block (411-1) is remapped and an entire additional memory block (411-2) is used to facilitate the correction of a single bit failure.

Accordingly, a memory manager (FIG. 1, 102) using a finer-grain remapping procedure such as a FREE-p remapping may remap individual memory locations (407) thus preserving additional resource memory blocks (411), such as those in the first row (409-1) and the second row (409-2), to be used for larger memory failures. For example, a small failure, such as a single bit failure (413) as indicated by the “x,” may occur on a sixth memory location (407-6) corresponding to a memory block (411-3) on the first memory die (408-1). In this example, the memory manager (FIG. 1, 102) may remap the sixth memory location (407-6) to a first memory location (407-1) as indicated by the arrow (412-2). In this example, the entire sixth memory location (407-6) may be remapped to the first memory location (407-1) regardless of the memory block (411) that includes the failure (413).

As can be seen from FIG. 4, using the memory manager (FIG. 1, 102) to remap memory locations (407) may be beneficial in that the additional resources are not used by a remapping procedure implemented by the memory manager (FIG. 1, 102), but are left available for use by the memory tester (FIG. 1, 101).

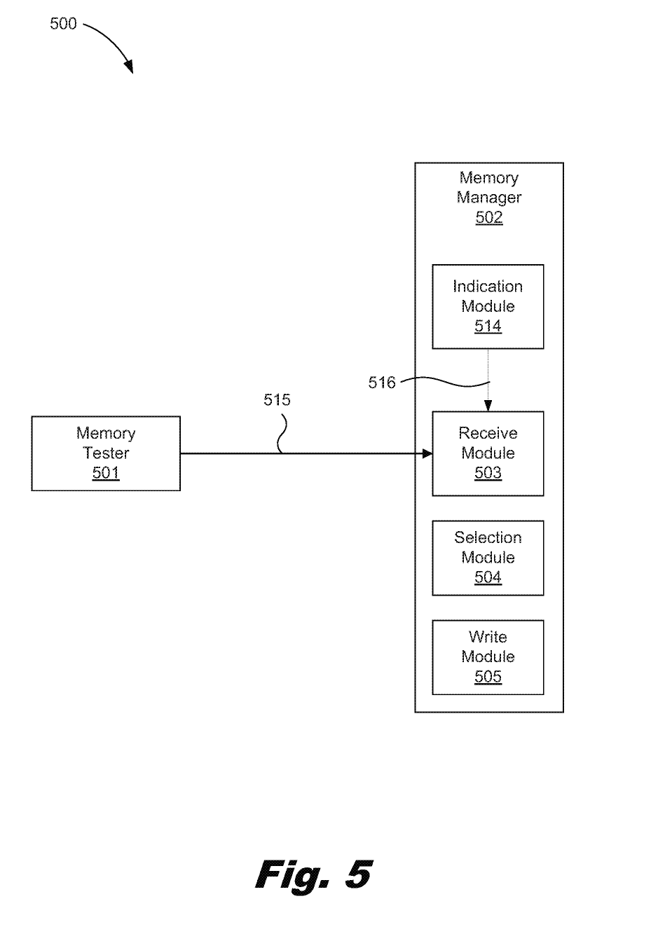

FIG. 5 is a diagram of a memory manager (502) for remapping memory locations (FIG. 1, 107) in in a memory array (FIG. 1, 106) according to one example of the principles described herein. The memory manager (502) may contain an indication module (514), a receive module (503), a selection module (504), a write module (505), or a combination thereof. The receive module (503) may receive an indication of a first memory location (FIG. 1, 107-1) within a memory array (FIG. 1, 106) that is to be remapped. As described above, in some examples, the receive module (503) may receive the indication from a memory tester (501) as indicated by the arrow (515). In this example, the indication may be included in a data file or a pattern within the memory. In some examples, the receive module (503) may receive the indication from an indication module (516) as indicated by the arrow (516).

The indication module (510) may function as part of a memory manager (502) to identify a memory location (FIG. 1, 107) in a memory array (FIG. 1, 102) to remap. The indication module (510) may test the entire memory array (FIG. 1, 106) in a single event or a consecutive series of events. The indication module (510) may also perform tests of the memory array (502) when the memory array (502) is either written to or read from. When the indication module (510) determines that a memory location (FIG. 1, 107) is experiencing an error, the indication module (510) may send the identification of the memory location (FIG. 1, 107) to a receive module (503). This communication may be performed via a number of data communication methods, including data files, inter-process communication messaging, intra-process communication messaging, networking protocols, or similar methods of communication. The memory manager (502) may include modules beyond those illustrated.

As described above, a memory tester (501) may perform remappings at a coarser granularity such as at a memory block (FIG. 4, 411) level. Doing so may require additional resources to compensate for failed memory blocks (FIG. 4, 411). By comparison, using a memory manager (502) to perform a finer grain remapping, such as a FREE-p remapping, may preserve more of the additional resources to be used for large memory block failures.

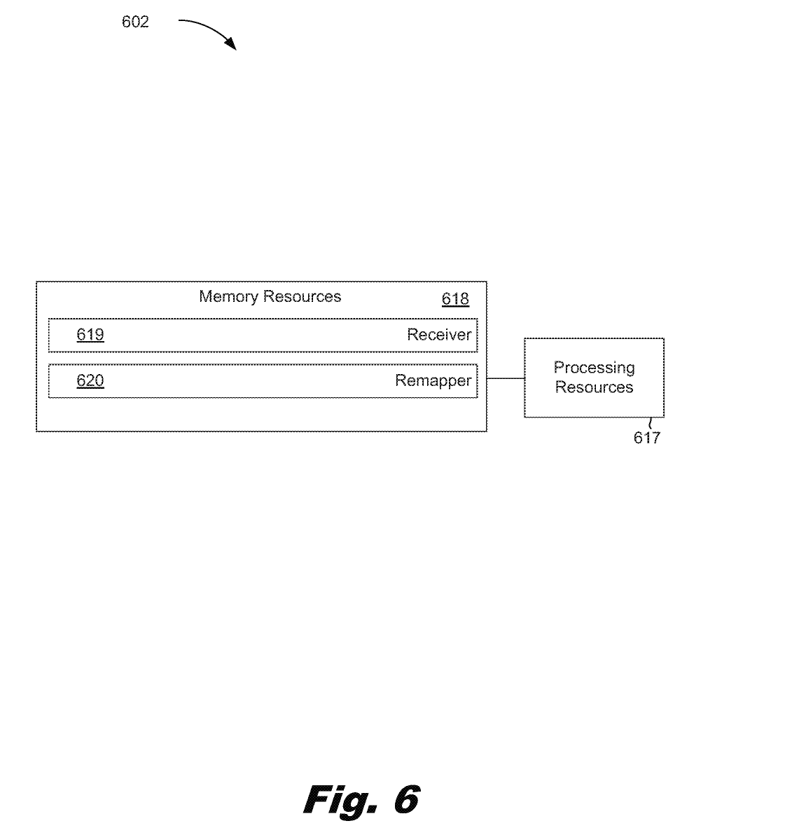

FIG. 6 is a diagram of a memory manager (602) for remapping memory locations (FIG. 1, 107) in a memory array (FIG. 1, 106) according to one example of the principles herein. The memory manager (602) may include the hardware architecture to retrieve executable code and execute the executable code. The executable code may, when executed by the memory manager (602), cause the memory manager (602) to implement at least the functionality of remapping memory locations (FIG. 1, 107) in a memory array (FIG. 1, 106), according to the methods of the present specification described herein. In the course of executing code, the memory manager (602) may receive input from and provide output to a number of the remaining hardware units.

In this example, the memory manager (602) may include processing resources (617) that are in communication with memory resources (618). Processing resources (617) may include at least one processor and other resources used to process programmed instructions. The memory resources (618) represent generally any memory capable of storing data such as programmed instructions or data structures used by the memory manager (602). The programmed instructions shown stored in the memory resources (618) may include a receiver (619) and a remapper (620).

The memory resources (618) include a computer readable storage medium that contains computer readable program code to cause tasks to be executed by the processing resources (617). The computer readable storage medium may be tangible and/or physical storage medium. The computer readable storage medium may be any appropriate storage medium that is not a transmission storage medium. A non-exhaustive list of computer readable storage medium types includes non-volatile memory, volatile memory, random access memory, write only memory, flash memory, electrically erasable program read only memory, or types of memory, or combinations thereof.

The receiver (619) represents programmed instructions that, when executed, cause the processing resources (617) to receive information about a first memory location (FIG. 1, 107-1) to be remapped. The remapper (620) represents programmed instructions that, when executed, cause the processing resources (617) to remap the first memory location (FIG. 1, 107-1) to a second memory location (FIG. 1, 107-2).

Further, the memory resources (618) may be part of an installation package. In response to installing the installation package, the programmed instructions of the memory resources (618) may be downloaded from the installation package's source, such as a portable medium, a server, a remote network location, another location, or combinations thereof. Portable memory media that are compatible with the principles described herein include DVDs. CDs, flash memory, portable disks, magnetic disks, optical disks, other forms of portable memory, or combinations thereof. In other examples, the program instructions are already installed. Here, the memory resources can include integrated memory such as a hard drive, a solid state hard drive, or the like.

In some examples. the processing resources (617) and the memory resources (618) are located within the same physical component, such as a server, or a network component. The memory resources (618) may be part of the physical component's main memory, caches, registers, non-volatile memory, or elsewhere in the physical component's memory hierarchy. Alternatively, the memory resources (618) may be in communication with the processing resources (617) over a network. Further, the data structures, such as the libraries, may be accessed from a remote location over a network connection while the programmed instructions are located locally. Thus, the memory manager (602) may be implemented on a user device, on a server, on a collection of servers, or combinations thereof.

Methods and systems for re-initializing a number of memory arrays (FIG. 1, 102) may have a number of advantages, including: (1) reducing the amount of additional memory resources needed; (2) improving part yield of a memory die; (3) allocating processing of memory remapping based on error size; and (4) improving remapping times.

Aspects of the present system and method are described herein with reference to flowchart illustrations and/or block diagrams of methods, apparatus (systems) and computer program products according to examples of the principles described herein. Each block of the flowchart illustrations and block diagrams, and combinations of blocks in the flowchart illustrations and block diagrams, may be implemented by computer usable program code. The computer usable program code may be provided to a processor of a general purpose computer, special purpose computer, or other programmable data processing apparatus to produce a machine, such that the computer usable program code, when executed via, for example, the processing resources (617) or other programmable data processing apparatus, implement the functions or acts specified in the flowchart and/or block diagram block or blocks. In one example, the computer usable program code may be embodied within a computer readable storage medium, the computer readable storage medium being part of the computer program product. In one example, the computer readable storage medium is a non-transitory computer readable medium.

The preceding description has been presented to illustrate and describe examples of the principles described. This description is not intended to be exhaustive or to limit these principles to any precise form disclosed. Many modifications and variations are possible in light of the above teaching.

What is claimed is:

1. A method or remapping a memory location in a memory array, comprising:
receiving, by a memory manager, an identification of a first memory location in a memory array that is to be remapped using a remapping procedure performed by a memory manager, the remapping procedure comprising:
selecting a second memory location to store data intended for the first memory location; and
writing, in the first memory location, a pointer to the second memory location.

2. The method of claim 1, in which the identification of the first memory location is received from a memory tester.

3. The method of claim 2, in which the identification of the first memory location is received in a data file, and in which the method further comprises reading, from the data file, the identification of the first memory location.

4. The method of claim 2, in which a memory block of the memory array is remapped by the memory tester, and in which the first memory location is distinct from the memory block of the memory array that is remapped by the memory tester.

5. The method in claim 1, in which receiving an identification of the first memory location comprises reading a pattern indicating that the first memory location is to be remapped.

6. The method of claim 1, in which receiving an identification of the first memory location further comprises identifying, by the memory manager, the first memory location that is to be remapped.

7. The method of claim 1, in which the remapping procedure uses a status bit to identify that a memory location has been remapped, and a remap pointer to indicate the second memory location.

8. The method of claim 1, in which the remapping procedure performed from the memory manager is performed with less memory utilization than a remapping performed by a memory tester.

9. The method of claim 1, in which the remapping procedure is a fine grained remapping with error checking and correcting and embedded pointers (FREE-p) mapping function.

10. A system for remapping a memory location in a memory array, comprising:
a processor;
memory communicatively coupled to the processor; and
a memory manager, the memory manager comprising:
a receiver to receive information about a first memory location to be remapped; and
a remapper to remap data intended for the first memory location to a second memory location.

11. The system of claim 10, in which the memory communicatively coupled to the processor comprises a number of memristor elements.

12. The system of claim 10, in which the memory communicatively coupled to the processor is a cross bar memory array.

13. The system in claim 10, in which the remapper remaps the data intended for the first memory location to a second memory location at a cache line granularity.

14. A computer program product for remapping memory locations in a memory array, the computer program product comprising:
a computer readable storage medium comprising computer usable program code embodied therewith, the computer usable program code comprising:
computer usable program code to, when executed by a processor, receive information regarding a first memory location in a memory array, in which the first memory location is to be remapped;
computer usable program code to, when executed by a processor, select a second memory location in a memory array to store data intended for the first memory location; and
computer usable program code to, when executed by a processor, remap the data intended for the first memory location to the second memory location.

15. The product of claim 14, further comprising:
computer usable program code to, when executed by a processor, identify the first memory location in the memory array that is to be remapped.
